(19) United States
(12) Patent Application Publication
(10) Pub. No.: US 2025/0211176 A1
(43) Pub. Date: Jun. 26, 2025

(54) SYSTEM AND METHOD FOR CONTROLLING AMPLIFIER

(71) Applicant: MACOM Technology Solutions Holdings, Inc., Lowell, MA (US)

(72) Inventor: Jacob REESE, Portland, OR (US)

(21) Appl. No.: 18/395,863

(22) Filed: Dec. 26, 2023

(51) Int. Cl. H03F 1/08

(52) U.S. Cl. CPC H03F 1/086; H03F 2200/144

(57) ABSTRACT

Systems, circuits, and methods for amplifying signals are provided. An illustrative amplifier circuit may include an amplifier that amplifies an input signal received at an input node of the amplifier and provides an amplified version of the input signal as an output signal at an output node of the amplifier, a feedback loop connected between the input node of the amplifier and the output node of the amplifier, and a synchronized gain tracking sub-circuit provided in the feedback loop, where the synchronized gain tracking sub-circuit synchronously controls both a feedback resistance and forward gain of the amplifier circuit.

### FIELD OF THE DISCLOSURE

The present disclosure is generally directed toward circuits and, in particular, toward amplifier circuits.

### BACKGROUND

In electronics, a transimpedance amplifier, (TIA) is a widely used device configured as a current-to-voltage converter. The TIA can be used to amplify the current output of sensors such as but not limited to photodetectors in fiber optic communication systems, as well as other types of sensors to generate a usable voltage. Current-to-voltage converters are also often used with sensors that have a current response that is more linear than the voltage response. This is the case with photodiodes where it is not uncommon for the current response to have better than 1% linearity over a wide range of light input. The transimpedance amplifier ideally presents a low impedance to the photodiode. One common factor of transimpedance amplifiers is an ability to convert the low-level current of a sensor to a voltage. The gain, bandwidth, current and voltage offsets change with different types of sensors (such as photodetectors), requiring different configurations of transimpedance amplifiers.

When configured in a communication system or data exchange system, the bandwidth of the transimpedance amplifier is of importance due to the trend for communication systems to operate at higher speeds with each new product release. One aspect of a TIA that affects bandwidth capabilities is an ability to support a wide range of input capacitance. This is an important requirement for TIA for optical communication applications. Maintaining sufficient bandwidth during operation of transimpedance amplifiers under various input capacitance is also an important requirement.

As demand continues to increase for high sensitivity of the TIA along with lower cost TIA designs, the main driving force is to replace the APD-based receivers (avalanche photodiode) with the PIN-based (p-i-n photodiode) type devices. APD-based receivers are more expensive due to higher cost to manufacture and require external circuitry to control temperature compensation.

A typical PIN-based (p-i-n photodiode) optical receiver includes a photodiode and a TIA. It is known that the photodiode capacitance at the input of a TIA can significantly degrade the bandwidth and the sensitivity. For applications demanding relatively high bandwidth requirements (e.g., up to 28 GHz or more), the control of amplifier forward gain and feedback gain becomes more important. PMOS transistors have been traditionally used to control forward amplifier gain while NMOS transistors have been used to control feedback resistance. Other methods of amplifier control have been developed to control the forward gain by adjusting the current of the main amplifying transistor. Existing control solutions have many drawbacks, which are exacerbated when the circuit(s) operate in high bandwidth applications.

### SUMMARY

Embodiments of the present disclosure are contemplated to improve the amplifier circuits. Specifically, but without limitation, embodiments of the present disclosure aim to provide a control circuit that simultaneously controls the forward gain of an amplifier (e.g., used in shunt-feedback TIAs) along with the feedback resistance. In some embodiments, the ratio between feedback resistance and forward gain is maintained in a substantially constant state, thereby stabilizing the transfer function of the TIA.

According to at least some embodiments, a pair of NMOS transistors may be used to control both the feedback resistance as well as the amplifier's forward gain. Utilizing the same type of NMOS transistor to control both aspects of the amplifier's performance helps to maintain consistency of performance over process/voltage/temperature variations. The pair of NMOS transistors may be controlled by a pair of PMOS current mirrors, which duplicate current flows into the pair of NMOS transistors. The duplicate current flows can help achieve a similar or identical gate-source voltage at both of the NMOS transistors in the pair of NMOS transistors. In some embodiments, the size of the gate-source voltages at each NMOS transistor in the pair of NMOS transistors may be set according to the desired shift of impedance that is required from the circuit. In some embodiments, the circuit may be configured to operate in high-bandwidth applications (e.g., up to 28 GHz or more).

In some embodiments, an amplifier circuit is provided that includes: an amplifier that amplifies an input signal received at an input node of the amplifier and provides an amplified version of the input signal as an output signal at an output node of the amplifier; a feedback loop connected between the input node of the amplifier and the output node of the amplifier; and a synchronized gain tracking sub-circuit provided in the feedback loop, where the synchronized gain tracking sub-circuit synchronously controls both a feedback resistance and forward gain of the amplifier circuit.

In some embodiments, a system is provided that includes: a photodiode that receives an input optical signal and produces an electrical signal in response thereto; and an amplifier circuit connected to the photodiode, where the amplifier circuit includes: an amplifier that amplifies the electrical signal received at an input node of the amplifier and provides an amplified version of the electrical signal as an output signal at an output node of the amplifier; a feedback loop connected between the input node of the amplifier and the output node of the amplifier; and a synchronized gain tracking sub-circuit provided in the feedback loop, where the synchronized gain tracking sub-circuit synchronously controls both a feedback resistance and forward gain of the amplifier circuit.

In some embodiments, a method is provided that includes: receiving an optical signal; converting the optical signal into an electrical signal; passing the electrical signal into one or more amplification circuits; synchronously adjusting a feedback gain and forward gain of the one or more amplification circuits to control amplification of the electrical signal in the one or more amplification circuits; and outputting an amplified electrical signal from the one or more amplification circuits.

The preceding is a simplified summary to provide a basic understanding of some aspects and embodiments described herein. This summary is not an extensive overview of the disclosed subject matter. It is neither intended to identify key nor critical elements of the disclosure nor delineate the scope thereof. The summary is provided to present some concepts in a simplified form as a prelude to the more detailed description that is presented later.

### BRIEF DESCRIPTION OF THE DRAWINGS

The present disclosure is described in conjunction with the appended figures, which are not necessarily drawn to scale:

FIG. 1 illustrates a first amplifier circuit according to at least some embodiments of the present disclosure;

FIG. 2 illustrates frequency response curves of an amplifier circuit according to at least some embodiments of the present disclosure;

FIG. 3 illustrates a second amplifier circuit according to at least some embodiments of the present disclosure;

FIG. 4 illustrates a third amplifier circuit according to at least some embodiments of the present disclosure; and

FIG. 5 illustrates a method of operating an amplifier circuit according to at least some embodiments of the present disclosure.

### DETAILED DESCRIPTION

It is with respect to the above-noted challenges that embodiments of the present disclosure were contemplated. In particular, a system, circuits, and method of operating such circuits are provided that solve the drawbacks associated with existing amplifier circuits.

While embodiments of the present disclosure will primarily be described in connection with amplifier circuits used in high-bandwidth applications, it should be appreciated that embodiments of the present disclosure are not so limited. Furthermore, while embodiments of the present disclosure are contemplated for use in controlling TIAs, it should be appreciated that embodiments of the present disclosure are not so limited.

Various aspects of the present disclosure will be described herein with reference to drawings that are schematic illustrations of idealized configurations. It should be appreciated that while particular circuit configurations and circuit elements are described herein, embodiments of the present disclosure are not limited to the illustrative circuit configurations and/or circuit elements depicted and described herein. Specifically, it should be appreciated that circuit elements of a particular type or function may be replaced with one or multiple other circuit elements to achieve a similar function without departing from the scope of the present disclosure.

It should also be appreciated that the embodiments described herein may be implemented in any number of form factors. Specifically, the entirety of the circuits disclosed herein may be implemented in silicon as a fully-integrated solution (e.g., as a single Integrated Circuit (IC) chip or multiple IC chips) or they may be implemented as discrete components connected to a Printed Circuit Board (PCB).

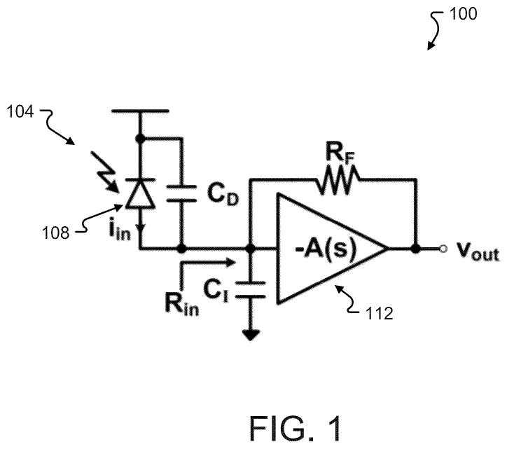

Referring initially to FIG. 1, a first amplifier circuit 100, or portion of an amplifier circuit, will be described in accordance with at least some embodiments of the present disclosure. The circuit 100 is configured to receive an input optical signal 104 at a photodiode 108. Capacitor CD represents the capacitance of the photodiode. The photodiode 108 may be configured to convert the optical signal 104 into an electrical signal, which is provided as an input electrical signal to an amplifier 112. Input capacitor CI represents the input capacitance of the amplifier 112. In some embodiments, the amplifier 112 may be configured to amplify the input signal received at its input node and generate an output signal at its output node. The output signal may include an output voltage Vout, which may be provided to another amplifier circuit or another type of circuit for further processing (e.g., a clock and data recovery (CDR) circuit).

The amplifier 112 may also have a feedback resistor RF connected between its output node and input node. The configuration of the circuit 100 and use of the feedback resistor RF may help a finite bandwidth amplifier 112 modify the transimpedance function to a second-order low-pass function. In other words, once the transit time of the amplifier becomes significant relative to the bandwidth target, the system acts as a second-order function.

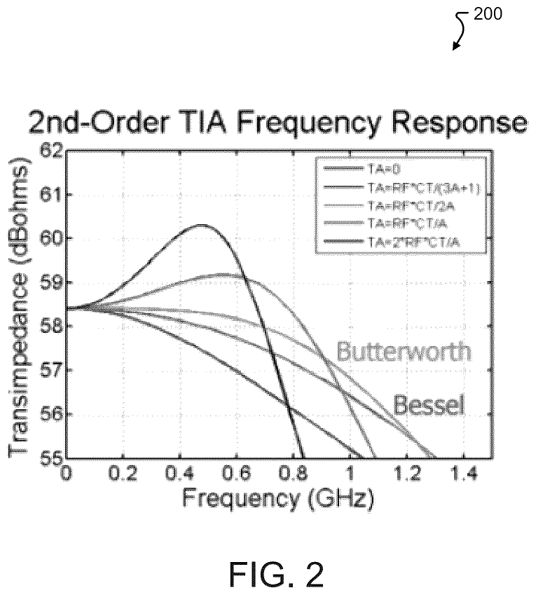

A non-zero amplifier time constant can increase amplifier 112 bandwidth. However, the non-zero amplifier time constant may also result in undesired peaking in the frequency domain and overshoot/ringing in time domain. As can be seen in FIG. 2, a transfer function plot shows that peaking changes may occur depending on the delay of the amplifier. Assuming the delay is fixed (which is an approximation), it becomes apparent that to keep the flat frequency response, the amplifier gain must move with the inverse of the feedback resistor RF. FIG. 2 illustrates a number of frequency response curves 200 that show peaking in the frequency domain if a non-zero amplifier time constant is used. FIG. 2 specifically illustrates frequency response curves 200 for either: (A) a Butterworth response where Q=1/sqrt(2) or (2) a Bessel response (Q=1/sqrt(3)) may be used. The Butterworth response gives maximally flat frequency response whereas the Bessel response a gives maximally flat group delay.

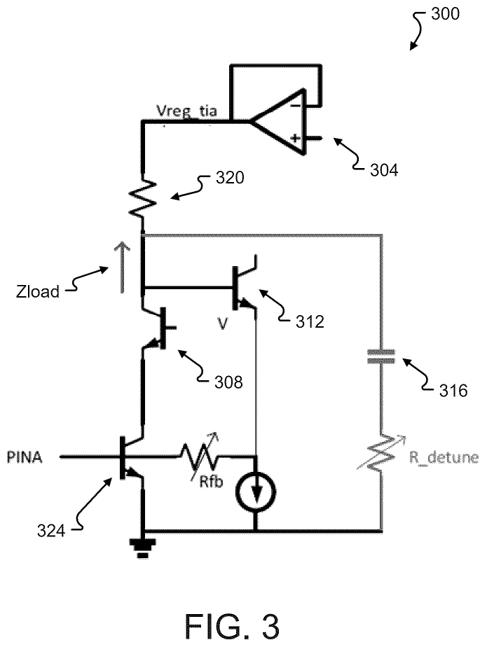

Referring now to FIG. 3, another amplifier circuit 300 will be described in accordance with at least some embodiments of the present disclosure. The circuit 300 is shown to include an amplifier 304. The amplifier 304 provides a regulated power supply voltage Vreg_tia for amplifier circuit 300. The circuit 300 differs from circuit 100 in that the feedback control loop comprises more than a feedback resistor RF.

The control feedback loop may include a resistor 320 that provides a load impedance Zload. The control feedback loop also includes a first transistor 308 connected in a cascode configuration and second transistor 312 connected to the output of the first transistor 308. The base of the first transistor 308 may be controlled by control circuitry whereas the base of the second transistor 312 may be connected to the collector of the first transistor 308. The emitter of the first transistor 308 may also be connected to a collector of a third transistor 324. The transistors 308, 312, 324 may work together to control a feedback resistor Rfb.

A capacitor 316 is also connected to resistor 320. The capacitor 316 may be connected in series with a detune resistor R_detune, which helps reduce the effective load resistance of the amplifier circuit 300. Specifically, and without limitation, the value of resistance provided by the detune resistor R_detune may be controlled by the combined efforts of the transistors 308, 312, 324. In the circuit 300 illustrated in FIG. 3, the forward gain may be expressed as gm*RL, where gm equals the collector current of transistor 324 divided by thermal voltage, V_{T}, and where RL is a load resistance, which is effectively the value of the detune resistor R_detune in parallel with the value of the resistor 320.

The feedback control loop may be provided to simultaneously control both the feedback resistor Rfb and the forward gain control, by adjusting the detune resistor R_detune. As shown in FIG. 3, both the feedback resistor Rfb and the detune resistor R_detune may be controllable/adjustable by operation of transistors 308, 312, 324 in the feedback control loop.

Attempts have been made to control the forward gain (e.g., the detune resistor R_detune) by simply adjusting the current I flowing through the resistor 320. This approach presents challenges in that it becomes difficult to keep the current I under control such that it tracks the control of the feedback resistor Rfb. Additionally, when the current I flowing through resistor 320 is low (e.g., when input current to the transimpedance amplifier becomes larger), the large signal behavior may become asymmetric.

Accordingly, it may be beneficial to provide an improved feedback control loop in which simultaneous control of the feedback resistor Rfb and the detune resistor R_detune is achieved by a mechanism that doesn't directly rely on controlling the current I flowing through resistor 320.

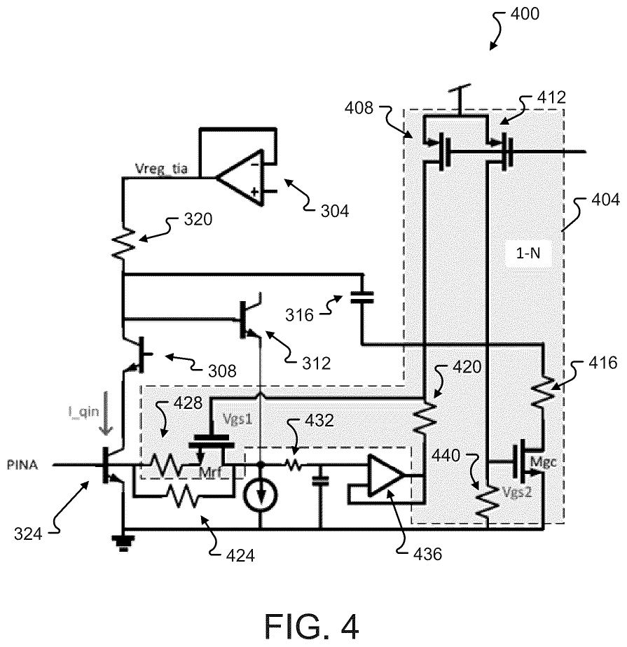

FIG. 4 illustrates an example of a circuit 400 which helps address the above-identified issues with other amplifier circuits. In particular, circuit 400 includes a synchronized gain tracking sub-circuit 404. In some embodiments, the synchronized gain tracking sub-circuit 404 is configured to synchronously control both a feedback resistor 428 and a detune resistor 416. The feedback resistor 428 may be similar or identical to feedback resistor Rfb and detune resistor 416 may be similar or identical to detune resistor R_detune.

As will be described in further detail herein, the feedback control loop may include multiple stages of the synchronized gain tracking sub-circuit 404. Specifically, but without limitation, the feedback control loop may include 1-N(where N is any integer number greater than one). Each of the N stages may be configured similarly to the illustrated stage of the synchronized gain tracking sub-circuit 404, except that values of circuit elements (e.g., resistors, capacitors, amplifiers, etc.) may differ from one stage to the next and timing associated with controls of each stage may differ from one stage to the next. In some embodiments, the number of stages N may be selected to create a substantially continuous (or approximation of continuous) resistance versus gain transfer function.

In some embodiments, each stage of the N stages may include a first NMOS transistor Mrf to control a feedback resistance value (e.g., to control/adjust the feedback resistor 428) of the feedback loop and a second NMOS transistor Mgc to control a detune resistance value of the feedback loop (e.g., to control/adjust the forward gain by controlling/adjusting the detune resistor 416).

Each stage of the N stages may also include a pair of PMOS transistors 408, 412 that are configured to control current flowing into the synchronized gain tracking sub-circuit 404. In some embodiments, a first PMOS transistor 408 may be provided as a first control transistor for controlling operation of the first NMOS transistor Mrf. A second PMOS transistor 412 may be provided as a second control transistor for controlling operation of the second NMOS transistor Mgc. The PMOS transistors 408, 412 collectively act as current mirrors to ensure that current flowing to the first NMOS transistor Mrf is substantially similar or identical to the current flowing to the second NMOS transistor Mgc. In some embodiments, the PMOS transistors 408, 412 are switched substantially synchronously with one another, which helps to ensure synchronous controls for both the feedback resistance 428 and the detune resistance 416.

The configuration of circuit 400 also helps set a gate-source voltage Vgs1 of the first NMOS transistor Mrf to be substantially equal to a gate-source voltage Vgs2 of the second NMOS transistor Mgc. The size of the gate-source voltages Vgs1, Vgs2 may be set according to a desired shift in impedance that is required of the circuit 400.

The circuit 400 is also shown to include a number of additional resistors and other circuit elements to support tuning and operation of the synchronized gain tracking sub-circuit 404. Illustratively, and without limitation, a first linking resistor 420 connects an output of a second amplifier 436 to a drain of the first PMOS transistor 408. A second linking resistor is provided between an input of the second amplifier 436 and a drain of the first NMOS transistor Mrf. A parallel feedback resistor 424 may also be provided across the feedback resistor 428. The parallel feedback resistor 424 may be connected to a drain of the first NMOS transistor Mrf. A parallel gain resistor 440 may also be provided across the second NMOS transistor Mgc. The value(s) of the resistors 416, 420, 424, 428, 432, 440, as well as the operating parameters of the second amplifier 436 may be selected based on a load resistance, target bandwidth, and switching speed desired for the circuit 400.

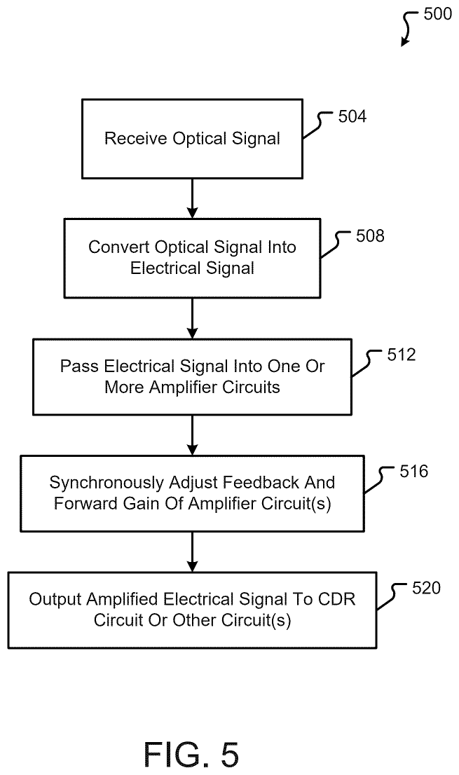

Referring now to FIG. 5, a method 500 of operating an amplifier circuit, such as amplifier circuit 400, will be described in accordance with at least some embodiments of the present disclosure. The method 500 begins when an optical signal is received at a circuit element (step 504). In some embodiments, the optical signal may be received at a circuit element configured to convert the optical signal into an electrical signal (step 508). For instance, the optical signal may be received via an optical fiber or over air. The optical signal may be received at one or more photodiodes that convert the optical signal into an electrical signal.

The method 500 may then proceed by passing the electrical signal into one or more amplifier circuits (step 512). For instance, an output of the photodiode may be connected, directly or indirectly, to an input of an amplifier circuit. In some embodiments, the amplifier circuit may include one or more amplifiers (e.g., a transimpedance amplifier) and one or more synchronized gain tracking sub-circuits. The one or more synchronized gain tracking sub-circuits may be configured to synchronously adjust feedback and forward gain of the one or more amplifier circuits (step 516). The one or more synchronized gain tracking sub-circuits may control amplification of the electrical signal in the one or more amplification circuits.

The method 500 may further include outputting the amplified electrical signal from the one or more amplifier circuits to a CDR circuit or other type of processing circuit (step 520). For instance, in a pipeline for processing optical signals received on a fiber optic connection, the amplified signal may be provided to another amplifier circuit and/or to a CDR circuit.

Specific details were given in the description to provide a thorough understanding of the embodiments. However, it will be understood by one of ordinary skill in the art that the embodiments may be practiced without these specific details. In other instances, well-known circuits, processes, algorithms, structures, and techniques may be shown without unnecessary detail in order to avoid obscuring the embodiments.

While illustrative embodiments of the disclosure have been described in detail herein, it is to be understood that the inventive concepts may be otherwise variously embodied and employed, and that the appended claims are intended to be construed to include such variations, except as limited by the prior art.

What is claimed is:

1. An amplifier circuit, comprising:
an amplifier that amplifies an input signal received at an input node of the amplifier and provides an amplified version of the input signal as an output signal at an output node of the amplifier;
a feedback loop connected between the input node of the amplifier and the output node of the amplifier; and
a synchronized gain tracking sub-circuit provided in the feedback loop, wherein the synchronized gain tracking sub-circuit synchronously controls both a feedback resistance and forward gain of the amplifier circuit.

2. The amplifier circuit of claim 1, wherein the synchronized gain tracking sub-circuit comprises a first transistor to control a feedback resistance value of the feedback loop.

3. The amplifier circuit of claim 2, wherein the synchronized gain tracking sub-circuit comprises a second transistor to control a detune resistance value of the feedback loop, which controls the forward gain of the amplifier circuit.

4. The amplifier circuit of claim 3, wherein the first transistor and the second transistor are a common type of transistor.

5. The amplifier circuit of claim 3, wherein the first transistor and the second transistor are both NMOS transistors.

6. The amplifier circuit of claim 3, wherein a gate-source voltage of the first transistor is equal to a gate-source voltage of the second transistor.

7. The amplifier circuit of claim 6, wherein the gate-source voltage of the first transistor is controlled with an output of a first control transistor, wherein the gate-source voltage of the second transistor is controlled with an output of a second control transistor, and wherein the first control transistor and the second control transistor are switched substantially synchronously.

8. The amplifier circuit of claim 1, wherein the synchronized gain tracking sub-circuit comprises a number (N) of stages, wherein each stage of the N stages comprises a first NMOS transistor to control a feedback resistance value of the feedback loop and a second NMOS transistor to control a detune resistance value of the feedback loop.

9. The amplifier circuit of claim 8, wherein N is greater than or equal to two.

10. The amplifier circuit of claim 8, wherein N is selected to create a substantially continuous resistance versus gain transfer function.

11. A system, comprising:
a photodiode that receives an input optical signal and produces an electrical signal in response thereto; and
an amplifier circuit connected to the photodiode, wherein the amplifier circuit comprises:
an amplifier that amplifies the electrical signal received at an input node of the amplifier and provides an amplified version of the electrical signal as an output signal at an output node of the amplifier;
a feedback loop connected between the input node of the amplifier and the output node of the amplifier; and
a synchronized gain tracking sub-circuit provided in the feedback loop, wherein the synchronized gain tracking sub-circuit synchronously controls both a feedback resistance and forward gain of the amplifier circuit.

12. The system of claim 11, wherein the synchronized gain tracking sub-circuit comprises a first transistor to control the feedback resistance of the feedback loop.

13. The system of claim 12, wherein the synchronized gain tracking sub-circuit comprises a second transistor to control a detune resistance value of the feedback loop, which controls the forward gain of the amplifier circuit.

14. The system of claim 13, wherein the first transistor and the second transistor are a common type of transistor.

15. The system of claim 13, wherein the first transistor and the second transistor are both NMOS transistors.

16. The system of claim 13, wherein a gate-source voltage of the first transistor is equal to a gate-source voltage of the second transistor.

17. The system of claim 16, wherein the gate-source voltage of the first transistor is controlled with an output of a first control transistor, wherein the gate-source voltage of the second transistor is controlled with an output of a second control transistor, and wherein the first control transistor and the second control transistor are switched substantially synchronously.

18. The system of claim 11, wherein the synchronized gain tracking sub-circuit comprises a number (N) of stages, wherein each stage of the N stages comprises a first NMOS transistor to control a feedback resistance value of the feedback loop and a second NMOS transistor to control a detune resistance value of the feedback loop.

19. A method, comprising:
receiving an optical signal;
converting the optical signal into an electrical signal;
passing the electrical signal into one or more amplification circuits;
synchronously adjusting a feedback gain and forward gain of the one or more amplification circuits to control amplification of the electrical signal in the one or more amplification circuits; and
outputting an amplified electrical signal from the one or more amplification circuits.

20. The method of claim 19, wherein the feedback and forward gain of the one or more amplification circuits is synchronously adjusted by providing a synchronized gain tracking sub-circuit in a feedback loop of the one or more amplification circuits, wherein the synchronized gain tracking sub-circuit synchronously controls both the feedback gain and the forward gain of the amplifier circuit, wherein the synchronized gain tracking sub-circuit comprises a first transistor to control a feedback resistance value of the feedback loop, and wherein the synchronized gain tracking sub-circuit comprises a second transistor to control a detune resistance value of the feedback loop.
